(19) United States
(12) Patent Application Publication
(10) Pub. No.: US 2006/0107523 A1
(43) Pub. Date: May 25, 2006

(54) Method of making a printed circuit board

(75) Inventors: Mike Blossfeld, South Lyon, MI (US); Luis F. Sanchez, Commerce Township, MI (US)

Correspondence Address: TAROLLI, SUNDHEIM, COVELL & TUMMINO L.L.P., 1300 EAST NINTH STREET, SUITE 1700, CLEVEVLAND, OH, 44114, US

(73) Assignee: TRW Inc.

(21) Appl. No.: 10/996,935

(22) Filed: Nov. 24, 2004

(51) Int. Cl. H05K 3/36

(52) U.S. Cl. 29/830; 29/832; 29/840; 29/851

(57) ABSTRACT

a method of making a printed circuit board including the steps of: providing a board with electrical conductor traces; applying a solder material to at least one selected location on a first side of the board; placing a first component on the first side of the board; heating the board and solder material to reflow the solder applied to the first side of the board to provide an electrical connection of the first component with a first conductor trace portion of the board; and then connecting a second component to the board and providing a nonsoldered electrical connection between the second component and a second electrical conductor trace portion of the board.

### FIELD OF THE INVENTION

The present invention relates to a method of making a printed circuit board.

### BACKGROUND OF THE INVENTION

There are several processes for making a printed circuit board. One such process includes the steps of first applying an adhesive to one side of a laminated board. Then, a solder paste including a mixture of flux and solder material is then applied to the one side. The solder paste sticks to the nonadhesive areas on the board. At least one electrical component is then mounted on the one side of the board by a pick and place machine and held to the board by the adhesive. The board is then heated in an oven to melt the solder material to join or solder the electrical component to the board. This step is commonly referred to as reflow soldering.

After the reflow soldering, another set of electrical components, such as switch modules, are then manually mounted to the board and secure to it by a solder process known as wave soldering. In a wave soldering process, the board is sprayed with flux and then solder by passing the board over a wave of molten solder produced by a pump. After wave soldering, the board is tested and any necessary touch up soldering is performed manually.

This process has several disadvantages. One is that many assembly steps are performed to mount the components thereby adding to the cost and time of assembly. Another is that the laminated board is heated several times from the soldering applications, which could cause the board to delaminate and become faulty. Also, the wave solder method for the electrical components produces inconsistent applications of the solder, which could cause the formation of clumps or balls of solder on the printed circuit board resulting in faulty electrical shorts. Further, the wave soldering process uses an excessive amount of flux.

### SUMMARY OF THE INVENTION

The present invention relates to a method of making a printed circuit board including the steps of providing a board with electrical conductor traces; applying a solder material to at least one selected location on a first side of the board; placing a first component on the first side of the board; heating the board and solder material to reflow the solder applied to the first side of the board to provide an electrical connection of the first component with a first conductor trace portion of the board; and then connecting a second component to the board and providing a nonsoldered electrical connection between the second component and a second electrical conductor trace portion of the board.

In another aspect of the present invention, a method of making a printed circuit board includes the steps of providing a board with electrical conductive traces; placing a first component on a first side of the board; soldering the first component by heating the board to provide an electrical connection of the first component with a first electrical conductive trace portion of the board; and then connecting a first switch to the board and providing a nonsoldered electrical connection between the first switch and a second electrical conductive trace portion of the board.

### BRIEF DESCRIPTION OF THE DRAWINGS

The foregoing and other features of the present invention will become apparent to one skilled in the art to which the present invention relates upon consideration of the following description of the invention with reference to the accompanying drawings, in which:

FIG. 1 is an exploded view of a electrical module having the printed circuit board according to the present invention;

FIG. 2 is a schematic side view of the printed circuit board of FIG. 1;

FIG. 3 is an end view of the rocker switch illustrated in FIG. 1;

FIG. 4 is a sectional view taken generally along line 4-4 in FIG. 3, showing parts of the rocker switch;

FIG. 5 is a flow chart illustrating the steps for making the printed circuit board;

FIGS. 6A and 6B are side views of portions of the rocker switch of FIGS. 4 and 5; and

FIGS. 7A-7C are views illustrating the installation of the rocker switch.

### DESCRIPTION OF A PREFERRED EMBODIMENT

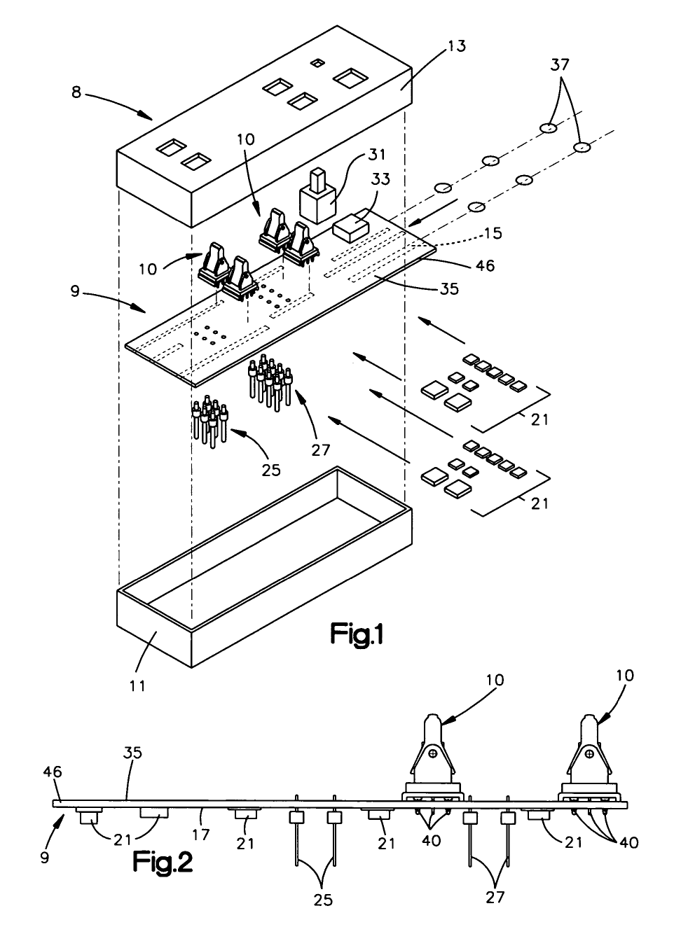

Referring to FIG. 1, an electrical module assembly 8 for operating windows and door locks for a vehicle is shown in exploded view. The electrical module assembly 8 includes a printed circuit board 9 that is placed upon a plastic base 11 and is located in a housing that includes the base 11 and a cover 13 mounted to the base 11.

The printed circuit board 9 includes a plastic laminated board 46. The laminated board 46 may include a layer of metal foil glued to a sheet of plastic (referred to as the substrate). The substrate may be layers of an epoxy glue reinforced with fiberglass. However, any other suitable materials can be used to form the board. The printed circuit board 9 is formed by selectively removing portions of the foil to form conductor traces 15 to which components 10, 31, 33, and 21 are electrically connected as also seen in FIG. 2.

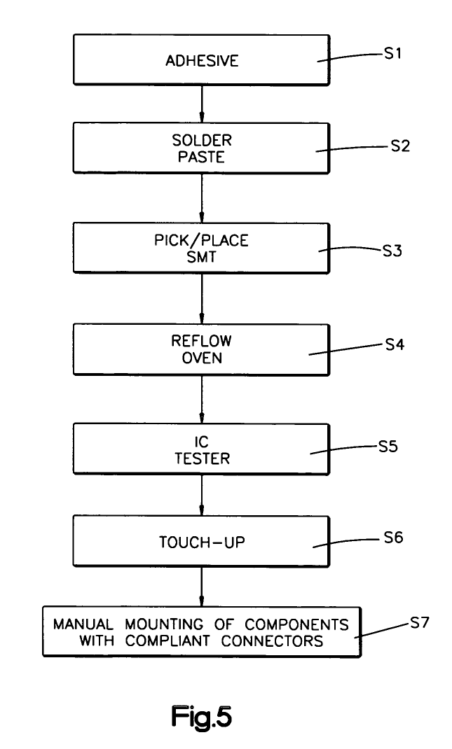

FIG. 5 illustrates the method of making the printed circuit board 9. In step (designated in the drawing by “S”) 1, an adhesive, designed to repel solder material, is first applied to the bottom side 17 (FIG. 2) of the board 46 at areas where solder material is not desired to be applied. In step 2, a silk-screened application of solder paste to selected areas of the bottom side 17 of the board occurs. The solder paste is a mixture of solder material and flux. The solder material is generally indium solder though any other suitable solder material could also be used.

In step 3, a plurality of first components 21 are then placed on the bottom side 17 of the board 46 by a pick and place machine and held to the board by the adhesive. These components 21 are generally electronic and designed to have small metal tabs or pads that may be directly soldered to the traces 15 of the board 46 to connect them to their respective traces 15. Six way connector terminals 25 and eight way connector terminals 27 are also placed on the bottom side 17 of the board 46 and are connected to a wire harness (not shown), which is electrically coupled to other devices on the vehicle such as a power source 16 and window motor 14 (FIG. 4).

In step 4, The board 46 is then heated by running it through a reflow oven to reflow the solder paste 19 applied to the bottom side 17 of the board 46 to provide a soldered electrical connection of the first components 21 and a conductor trace 15 of the board 46. In essence, this reflow soldering is a method which uses a heat source, such as an oven, to melt the solder material, after it has been applied to the board, to join the first components 21 to the board.

In step 5, the board 46 is then tested by an IC tester for faults. In step 6, any necessary manual touch up soldering is performed.

In step 7, a plurality of second components 10, 31, 33 usually in the form of electromechanical devices are then mounted to the top side 35 of the board and connected to the board such that a nonsoldered electrical connection is created between the second components and respective electrical conductor traces 15 of the board 46.

One of the second components is shown as a rocker switch assembly 10 used to operate a device. The device may be any device on a vehicle, such as a window, a seat, a mirror, or the like. In this embodiment of the invention described, the rocker switch assembly 10 operates a window. However, those skilled in the art, will appreciate that the switch of the present invention may control a device other than the windows for a vehicle. Also, other types of components to operate other devices could be used instead of the rocker switch assembly.

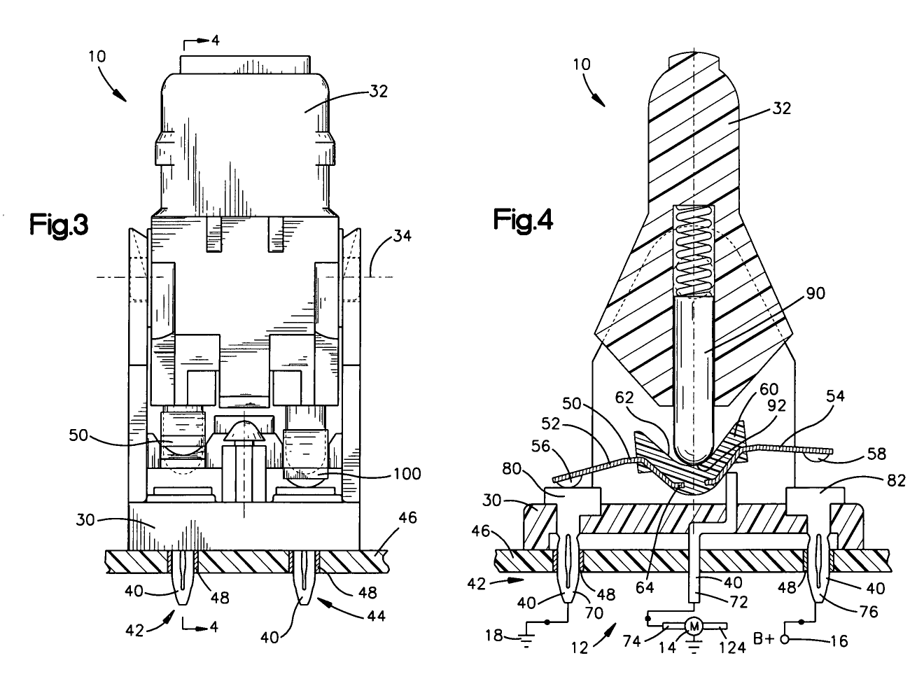

FIGS. 3 and 4 illustrate the rocker switch assembly 10 (hereinafter “rocker switch”). The rocker switch 10 is implemented in a system 12 (shown schematically in FIG. 4 that includes an electric window motor 14 and a vehicle electrical system including an electrical power source in the form of a battery 16 and a ground 18. The rocker switch 10 controls operation of the electric motor 14 for raising and lowering a vehicle window (not shown). The electric motor 14 is capable of bi-directional rotation, i.e., a reversible motor, such as a DC motor. As will be described herein below, the rocker switch 10 of the present invention may provide “manual” control of the operation of the electric motor 14 (and thus the vehicle window), and may also provide some “automatic” control of the operation of the electric motor.

Referring to FIGS. 3 and 4, the rocker switch 10 includes a base 30 that supports an actuator in the form of a lever 32 for pivotal or rotational movement about an axis 34. A series of terminals 40 protrude from a lower surface 36 of the base 30 of the rocker switch 10. In the illustrated embodiment, the rocker switch 10 includes six such terminals 40 arranged in first and second rows 42 and 44. The terminals 40 are for connecting the rocker switch 10 to plated-through holes 48 of the board 46 for the printed circuit board 9 (FIGS. 1 and 2). The terminals 40 may thus carry electrical signals between the rocker switch 10 and the other portions of the system 12 via the printed circuit board 9, as will be described herein below.

Referring to FIG. 3, the rocker switch 10 includes first and second switch members 50 and 100 associated with the first and second rows 42 and 44 of terminals 40, respectively. Referring to FIG. 4, the first switch member 50 includes a first contact arm 52 and an opposite second contact arm 54. The first and second contact arms 52 and 54 are in electrical contact with each other and may, for example be formed of a single piece of metal material, such as copper or a copper alloy. The first and second contact arms 52 and 54 each may include a domed contact portion 56 and 58, respectively.

The first switch member 50 is supported by a body portion 60 that may be formed of a material, such as plastic. The first switch member 50 may thus be insert molded in the body portion 60. The body portion 60 includes an upper actuator surface 62 and an opposite lower rocker surface 64. The first and second contact arms 52 and 54 each have a portion exposed on the rocker surface 64 of the body portion 60.

As shown in FIG. 4, the first switch member 50 is associated with the three terminals 40 in the first row 42. Among these terminals are a terminal 70 connected to ground, a terminal 72 connected to a first directional input 74 of the motor 14, and a terminal 76 connected to the battery 18. The terminals 70, 72, and 76 are formed of an electrically conductive material, such as metal, and may be connected to the base 30 by suitable means, such as by insert molding or press fitting the terminals into the base. The ground terminal 70 includes a contact portion 80 presented toward the contact portion 56 of the first contact arm 52. The battery terminal 76 includes a contact portion 82 presented toward the contact portion 58 of the second contact arm 54.

The rocker surface 64 of the body portion 60 is supported by the base 30 of the rocker switch 10 and/or the motor terminal 72. In this configuration, the first switch member 50 is maintained in electrical contact with the motor terminal 72. A spring biased actuator pin 90 supported in the lever 32 has a domed end surface 92 that rides on the actuator surface 62 of the body portion 60 and helps maintain the body portion and first switch member 50 supported on the base 30 and/or motor terminal 72. The second switch member 100 is similar in construction as the first switch member and further details of the second switch and the related parts are disclosed in commonly owned co-pending application having Ser. No. 10/693,508; the disclosure of which is hereby incorporated by reference.

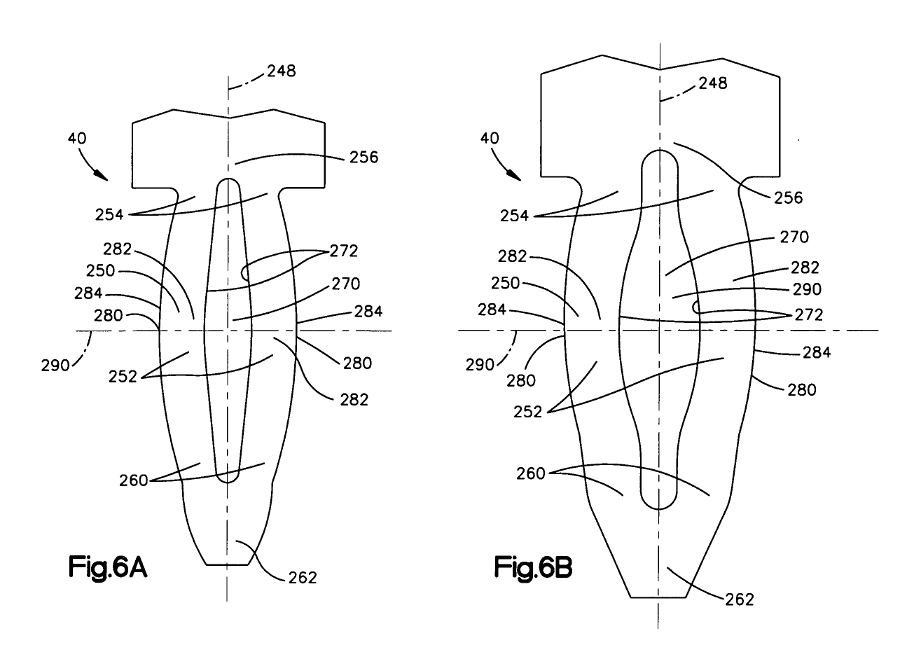

According to the present invention, each of the terminals 40 for each of the Rocker switches 10 and the other electrical components 31 and 33 comprises what may be referred to as a compliant connector pin or a compliant pin. Compliant pins are given this name because they deflect, deform, or otherwise comply with a hole or aperture into which they are press-fitted in order to form an interference fit. This interference fit helps connect the compliant pin to a member in which the hole or aperture extends. The terminals 40 may have a variety of compliant pin configurations. By way of example, two such compliant pin configurations are illustrated in FIGS. 6A and 6B. Each terminal 40 of the rocker switch 10 may be formed according to either of the compliant pin configurations illustrated in FIGS. 6A and 6B.

Referring to FIGS. 6A and 6B, the compliant pin portion 250 of the terminal 40 may include a pair of spaced beam portions 252. As shown in FIG. 6A, the beam portions 252 may be spaced symmetrically with respect to an axis 248 of the pin portion 250. The beam portions 252 each have first end portions 254 that merge with each other at an interface end 256 of the pin portion 250. The interface end 256 merges with the respective portions of the terminals 40 that are secured to the base 30 of the rocker switch 10 (see FIG. 4). The beam portions 252 each have second end portions 260, opposite the first end portions 254, that merge with each other at terminal insertion end 262 of the pin portion 250. The pin portion 250 includes a central opening 270 that is defined by opposing inner surfaces 272 of the beam portions 252. The inner surfaces 272 may have a variety of configurations or contours, such as straight, flat, curved, and cylindrical.

The beam portions 252 each include an outer surface 280 that are presented facing outward, that is, away from each other and away from the axis 248. The outer surfaces 280 help define an outer surface of the pin portion 250. The outer surfaces 280 may include a combination of cylindrical, flat, or curved surfaces that are blended or intersect each other to form an outer contour of the pin portion 250. In the embodiments of both FIGS. 6A and 6B, the contour of the pin portion 250 is such that the interface end 256 and insertion end 262 have a narrowed or tapered configuration. The pin portion 250 tapers outward from the axis 248 or widens between the interface end 256 and insertion end 262.

The pin portion 250 has an interface portion 282 that includes respective portions of the beam portions 252. The interface portion 282 includes an interface surface 284 of each of the outer surfaces 280 of the beam portions 252. The interface surfaces 284 include the widest portion of the pin portion 250 as measured along a lateral axis 290 of the pin portion, which extends perpendicular to the longitudinal axis 248. The interface surfaces 284 are rounded, curved, or cylindrical in the region of the lateral axis 290 and merge with an insertion surface 286 that extends along the insertion end 262 of the pin portion 250. As shown in FIG. 6A, the interface portion 282 of the pin portion 250 may include portions of each of the beam portions 252 that are widened in comparison with the remainder of the beam portions.

The electrically conductive material used to construct the terminals 40 may be a metal alloy. The contact 10 may, for example, be stamped from a metal alloy sheet stock material using a die that is cut to form the desired configuration. The metal sheet stock material may, for example, be a copper alloy, such as a tin-brass alloy or phosphor-bronze alloy, or could be alloys of other metals, such as stainless steel. These metals may be tempered or otherwise treated to provide desired qualities, such as hardness, tensile strength, and yield strength, and may also be coated or otherwise treated to provide corrosion resistance.

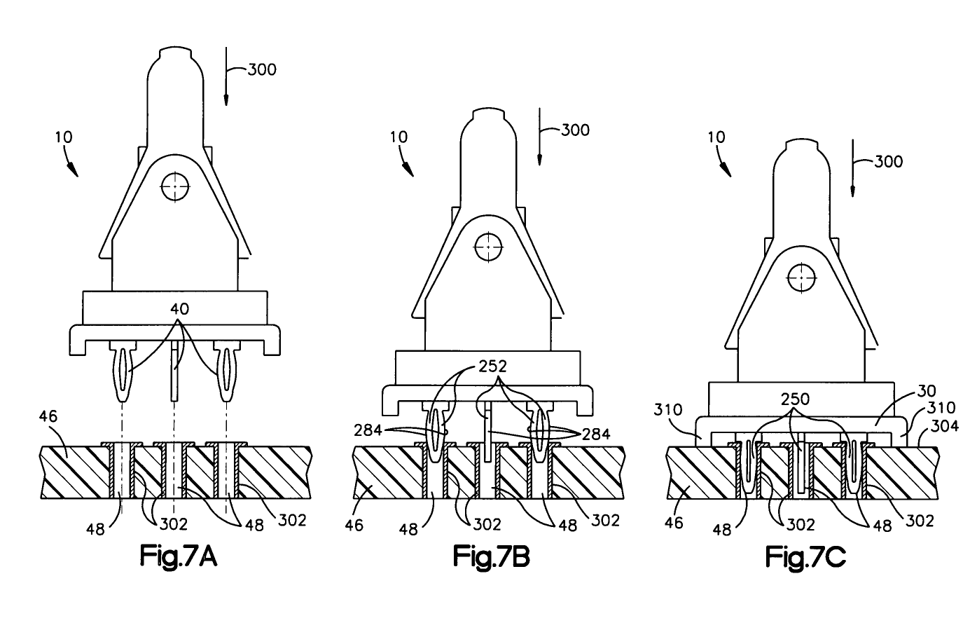

As a result of the compliant pin construction of the terminals 40, the rocker switches 10 and other components 31 and 33 of the present invention may be installed in a quick and reliable manner without the use of solder or other materials, such as adhesives or fasteners. This is shown in FIGS. 7A-7C. Referring to FIG. 7A, the rocker switch 10 is positioned with the terminals 40 presented toward the printed circuit board 46. The rocker switch 10 is directed in a downward direction indicated generally by the arrow labeled 300 toward the plated through-holes 48 in the circuit board 14. Each of the through-holes 48 has a side wall 302 that is plated, coated, or otherwise formed with an electrically conductive material (e.g., copper, silver, gold, nickel, tin-lead, or combinations or alloys thereof). The side wall 302 is electrically connected to a trace 15.

Referring to FIG. 7B, as the rocker switch 10 moves in the downward direction 300, the interface surfaces 284 of the beam portions 252 engage the printed circuit board 46. More specifically, the interface surfaces 284 of the beam portions 252 engage diametrically opposite locations on the side wall 302 of the through-hole 48 adjacent the intersection of the side wall and an upper surface 304 of the circuit board 46. As shown in FIG. 7B, the interface portions 282 of the pin portion 250 form an interference with the through-hole 48. More specifically, an interference is formed between the interface surfaces 284 of the beam portions 252 and the side wall 302.

Referring to FIG. 7C, as the rocker switch 10 moves farther in the downward direction 300, the beams 252 are urged toward each other as a result of normal forces exerted on the interface portions 282 by the side wall 302 of the through-hole 48. As the pin portion 250 enters the through-hole 48, the beam portions 252 deflect toward each other in a direction generally along the lateral axis 290. Also, as the rocker switch 10 moves farther in the downward direction 300, the interface surfaces 284 of the beam portions 252 slide past the intersection of the side wall 302 and the upper surface 304 of the printed circuit board 46. Once the interface portions 282 enter the through-hole 48, the interface surfaces 284 slide along the side wall 302.

When the beam portions 252 deflect as a result of the pin portion 250 being inserted into the through-hole 48, they exert a force on the side wall 302. This force is caused by the resilience of the material used to construct the terminals 40. The material construction of the terminals 40 causes the beam portions 252, when deflected toward each other, to have a spring bias that urges the beam portions away from each other and toward the side wall 302. Thus, when the terminals 40 are inserted into the through-hole 48 and the beam portions 252 are urged toward each other, the beam portions are biased in an opposite direction into engagement with the side wall 302 of the through-hole 48. This causes a frictional engagement between the interface surfaces 284 of the beam portions 252 and the side wall 302. Since the side wall 302 may be plated or otherwise coated with an electrically conductive material, this engagement may also result in an electrically conductive connection between the terminals 40 and their respective side walls and thereby between any devices (e.g., the motor 14) connected with the rocker switch 10 via the traces 15 of the circuit board 46.

As the pin portion 250 is urged into the through-hole 48, the side wall 302 may also be deformed as the interfaces portions 282 cut into or gouge the electrically conductive material of the side wall. This deformation may help promote or enhance the frictional engagement between the interface portions 282 and the side wall 302. It will be appreciated that the amount of frictional engagement between the beam portions 252 and the side wall 302 can be adjusted to desired levels by altering the material construction of the terminals 40 and/or the side wall, by altering the amount of interference between the interface portions 282 and the side wall, and also by altering the configuration of the compliant pin portion 250.

As the terminals 40 are moved in the downward direction 300 into the installed condition of FIG. 7C, leg portions 310 of the base 30 engage the upper surface 304 of the circuit board 46. This helps prevent over-insertion of the terminals 40 into their respective through-holes 48. This also helps ensure that the rocker switch 10 is placed in a desired position relative to the circuit board 46 when in the installed condition. Further details of the rocker switch assembly are disclosed in commonly owned co-pending patent application having Ser. No. 10/693,508; the disclosure of which is hereby incorporated by reference.

As shown in FIG. 1, four rocker switches 10 are mounted to the top side 35 of the board 46 and are each electrically connected to its respective motor 14 (FIG. 3) used to control the up and down window movements of the vehicle. One of the rocker switches 10 may also include an auto down function that automatically lowers the window fully to the open position after a momentary depression of the rocker switch 10. One of the second components is a window lock out switch 31 mounted to the top side 35 of the board 46.

The window lockout switch 31 includes a compliant pin 40 that is also inserted through a through hole 48 of the board 46 and retained therein. The compliant pin 40 and associated through hole 48 is similar in design and function as the compliant pin 40 and associated through hole 48 for the rocker switches 10. The window lock out switch 31 provides a nonsoldered electrical connection to each of the rocker switches 10 through their respective electrical conductor traces 15. Pressing the window lock out switch 31 one way opens the circuits between the rocker switches 10 and their respective motors 14 to disable the operation of all of the windows. Pressing the window lock out switch 31 the other way closes the circuits between the rocker switch assemblies 10 and their respective motors 14 to enable the operation of all of the windows by the rocker switches 10.

Another one of the second components is a door lock switch 33 mounted to the top side 35 of the board 46 for unlocking a door of the vehicle. The door lock switch 33 also includes a compliant pin 40 that is inserted through a through hole 48 of the board 46 and retained therein. The compliant pin 40 and associated through hole 48 is also similar in design and function as the compliant pin 40 and associated through hole 48 for the rocker switches 10. Optionally, illumination devices 37 can be positioned under the board to provide illumination to the second components 10, 31, and 33.

Thus, because of the mounting structure of the second components, this method of making the printed circuit board 9 uses only one step to heat the board and also eliminates the additional steps and material to solder the second components to the board, thereby reducing cost and improving quality.

From the above description of the invention, those skilled in the art will perceive improvements, changes and modifications. Such improvements, changes and modifications within the skill of the art are intended to be covered by the appended claims.

Having described the invention, the following is claimed:

1. A method of making a printed circuit board comprising the steps of:
a) providing a board with electrical conductor traces;
b) applying a solder material to at least one selected location on a first side of the board;
c) placing a first component on the first side of the board;
d) after steps (a), (b) and (c) heating the board and solder material to reflow the solder applied to the first side of the board to provide an electrical connection of the first component with a first conductor trace portion of the board; and
e) connecting a second component to the board and providing a nonsoldered electrical connection between said second component and a second electrical conductor trace portion of said board.

2. The method of claim 1 wherein said second component is a first switch for operating a first window of a vehicle.

3. The method of claim 1 wherein said board is laminated, and said heating step is the only heating of the board during the method.

4. The method of claim 2 including the steps of: connecting a second switch for operating a second window of said vehicle to the board and providing a nonsoldered electrical connection between said second switch and a third electrical conductor trace portion of the board, connecting a third switch for operating a third window of said vehicle to the board and providing a nonsoldered electrical connection between said third switch and a fourth electrical conductor trace portion of the board, connecting a fourth switch for operating a fourth window of said vehicle to the board and providing a nonsoldered electrical connection between said fourth switch and a fifth electrical conductor trace portion of the board.

5. The method of claim 4 including the step of: providing a nonsoldered electrical connection between a window lock switch for disabling the operation of the first, second, third, and fourth windows by their respective first second, third, and fourth switches and a sixth electrical conductor trace portion on said board.

6. The method of claim 2 including the step of: connecting to said first side of said board a window lock switch for disabling the operation of the first window by said first switch.

7. The method of claim 1 including the step of: applying an adhesive on other selected locations of the first side of the board before applying the solder material such that the solder material is directed away from the other selected locations in which the adhesive is applied.

8. The method of claim 1 including the step of: testing the first component on the first side of the board after step d.

9. The method of claim 1 wherein said second component is provided with compliant pins and said connecting step includes inserting the compliant pins into respective openings in the board to mount the second component to the board and provide said nonsoldered electrical connection with said second electrical conductor trace portion of the board.

10. The method of claim 1 wherein said second component is mounted on a second side of the board opposite the first side the board.

11. A method of making a printed circuit board comprising the steps of:
a) providing a board with electrical conductive traces;
b) placing a first component on a first side of the board;
c) soldering the first component to provide an electrical connection of the first component with a first electrical conductive trace portion of the board, said soldering step including heating said board; and
d) connecting a first switch to the board and providing a nonsoldered electrical connection between said first switch and a second electrical conductive trace portion of said board.

12. The method of claim 11 including the steps of: connecting said first switch to operate a first window of a vehicle, connecting a second switch for operating a second window of said vehicle to the board and providing a nonsoldered electrical connection between said second switch and a second electrical conductive trace portion, connecting a third switch for operating a third window of said vehicle to the board and providing a nonsoldered electrical connection between said third switch and a third electrical conductive trace portion, connecting a fourth switch for operating a fourth window of said vehicle to the board and providing a nonsoldered electrical connection between said fourth switch and a fourth electrical conductive trace portion.

13. The method of claim 11 including the steps of: connecting a window lock switch for disabling the operation of the first, second, third, and fourth windows by their respective first second, third, and fourth switches to provide a nonsoldered electrical connection of said window lock switch with a fifth electrical conductive trace portion.

14. The method of claim 11 including the step of: electrically connecting to said first side of said board a window lock switch for disabling the operation of the first window by said first switch.

15. The method of claim 11 wherein said first switch is mounted on a second side of the printed circuit board opposite the first side of the printed circuit board.

16. The method of claim 12 wherein said first, second, third, and fourth switches are mounted on a second side of the printed circuit board opposite the first side of the printed circuit board.
